(19) United States
(12) Patent Application Publication
(10) Pub. No.: US 2016/0299038 A1
(43) Pub. Date: Oct. 13, 2016

(54) SYSTEM AND METHOD FOR REMOTELY INFERRING CHARACTERISTICS OF THERMOSTAT-CONTROLLED APPLIANCES

(71) Applicant: Palo Alto Research Center Incorporated, Palo Alto, CA (US)

(72) Inventors: Victor Liu, Mountain View, CA (US); Sylvia Joan Smullin, Menlo Park, CA (US)

(21) Appl. No.: 14/682,666

(22) Filed: Apr. 9, 2015

(51) Int. Cl. G01M 99/00; F25D 29/00; G01R 21/133

(52) U.S. Cl. CPC G01M 99/005; G01R 21/133; F25D 29/00; F25D 2700/00

(57) ABSTRACT

A system for monitoring and analyzing the power consumption of a thermostat-controlled cycling appliance includes a detector configured to sample power consumption to obtain a power consumption time series having resolution sufficient to extract power cycle information for one or more individual components of a thermostat-controlled cycling appliance such as a refrigerator. An analyzer extracts the power cycle information from the sampled power consumption time series, compares the power cycle information to stored information of known power cycle characteristics and classifies the technology of one or more thermostat-controlled cycling appliance components based on comparison of the power cycle information to the stored information. The analyzer is further configured to generate an output that indicates the technology.

### TECHNICAL FIELD

This disclosure generally involves appliances with cycling behavior, including thermostat-controlled appliances such as refrigerators, and to systems and methods related to these appliances.

### BACKGROUND

Thermostat-controlled appliances are designed to maintain the temperature of a particular volume of space at a nearly constant temperature. Examples include appliances such as water heaters and furnaces, in which the temperature of a tank of water or the interior of a building is being controlled, respectively. The volume of space typically exchanges heat with its surrounding environment parasitically through imperfect thermal insulation. A subset of such thermostat-controlled appliances is thermostat-controlled heat pumps. Heat pumps are devices that transfer heat energy from one thermal bath (typically a thermally insulated chamber) to another, accomplishing this task by drawing power from an external source. Typically, a device containing a heat pump strives to maintain a nearly constant temperature in one of the thermal baths by using a feedback control system. Examples of thermostat-controlled heat pumps include air conditioners for cooling buildings, refrigerators for cooling food, ground-sourced heat pumps for heating buildings. In the example of a refrigerator, the heat pump (typically in the form of a vapor compression system) transfers heat from the refrigerated chamber to the ambient, while maintaining the chamber at a nearly fixed cold temperature. The external power source is typically the mains power supply, and the control mechanism is based on a thermostat with bang-bang control of the vapor compression pump. Due to the nature of bang-bang control, the vapor compression pump cycles between on and off states. This disclosure describes the inference of characteristic and components of thermostat-controlled cycling appliances in general (with refrigerators as a particular instance) based on power consumption of such devices. In the example of a refrigerator, the controlled temperature is the colder temperature and the exterior temperature is (presumably) warmer than the interior of the refrigerator. With a change of sign where appropriate, this same analysis applies to heat pumps, such as a ground-sourced heat pump used to heat a home, where the controlled environment is the hotter temperature and the exterior temperature is the colder temperature.

Refrigerators are one of the higher energy consuming appliances in single family homes. Generally, appliances that are newer and/or more technologically advanced cost less and cause less pollution than older, less technologically advanced appliances. For example, older refrigerators may have poor insulation, degraded seals, and/or may rely on compressor and defroster components that require more energy than newer models. Often consumers are unaware or are only partially aware of the relative energy efficiency of the appliances they use.

### SUMMARY

Some embodiments are directed to a system for use with a thermostat-controlled cycling appliance. The system includes a detector configured to sample power consumption to obtain a power consumption time series having resolution sufficient to extract power cycle information for one or more components of the appliance. A power cycle of a component includes a period of time when the component is on and the immediately preceding or following period of time when the component is off. For example, the power cycle information may be extracted by determining durations of time in which the one or more components of the appliance are active (“on”) and durations of time in which the components are inactive (“off”). The duty cycle fraction (or simply duty cycle) of a power cycle is defined as the ratio of the duration of time in one power cycle in which the component is on divided by the time duration of the power cycle:

$$Duty cycle = \frac{{t}_{n}}{{t}_{n} + {t}_{f}} .$$

An analyzer extracts the power cycle information from the sampled power consumption time series, compares the power cycle information to stored information of known power cycle characteristics and classifies technology of one or more components of the appliance based on comparison of the power cycle information to the stored information. In the particular instance of a refrigerator, such an analyzer may classify the technology of the defroster and compressor components of the refrigerator. The analyzer generates an output that indicates the technology. This comparison may be a comparison to a library of information about similar systems or it may be a comparison to measurements from systems in other facilities, for example.

According to some aspects, the analyzer is further configured to use the power cycle information to determine one or more of usage patterns of the refrigerator and fault or degradation conditions of the refrigerator.

According to some aspects, the analyzer is configured to identify components of the refrigerator, wherein the components include one or more of a defroster, an ice-maker, a water dispenser, and a chamber light.

According to some aspects, the one or more components include a defroster and the analyzer is configured to identify the technology of the defroster as one of timed defroster technology and a sensor-controlled defroster technology based on time intervals between power cycles of the defroster.

According to some aspects, the one or more components include a component that draws outside power in order to provide the work that drives the thermodynamic cycle, such as an electricity-driven compressor in a vapor-compression system. The analyzer may be configured to identify the technology of the component. For example, in some implementations, the analyzer may identify the compressor component as a vapor-compression system. In the case of a vapor-compression system, the analyzer may further identify the compressor as one or more of a variable speed compressor technology, and fixed speed compressor technology based on detection of at least one of amplitude spikes in the power cycles of the compressor and dynamically changing amplitude of the power cycles of the compressor.

According to some aspects, the analyzer is further configured to classify one or more of brand of the refrigerator, model of the refrigerator, and age of the refrigerator.

According to some aspects, the analyzer is configured to determine a readiness for replacement/recycling indicator for the refrigerator based on one or more of the brand, model and age of the refrigerator.

According to some aspects, the analyzer is further configured to detect one or more of refrigerator fault and degradation conditions from the power cycle information. For example, analyzer can be configured to detect the refrigerator fault and/or degradation conditions based on one or a combination of long time scale information collected over more than one month and short time scale information collected over less than one hour. The analyzer may be configured to use the long time scale information to establish a baseline of performance of the refrigerator and to compare the short time scale information to the baseline to detect a sudden fault condition.

According to some aspects, the analyzer is configured to use the long time scale information to compare power cycle information of the refrigerator under similar ambient conditions. According to some aspects, the power cycle information comprises one or more power cycle parameters and the analyzer is configured to detect degradation based on transient analysis of the one or more power cycle parameters.

According to some aspects, the analyzer is configured to determine usage patterns of the refrigerator based on variability in the power cycles of the refrigerator.

Some embodiments are directed to a method that includes sampling power consumption at a frequency sufficient to discern power cycles for one or more individual components of a multi-component refrigerator, comparing power cycle information obtained from the sampled power consumption to stored information of known power cycle characteristics, classifying technology of the components of the refrigerator based on comparison of the power cycle information to the stored information, generating an output that indicates the technology.

According to some aspects, the method further includes determining brand, model and/or age of the refrigerator based on the technology of the components.

According to some aspects, the method further includes determining usage patterns of the refrigerator.

According to some aspects, the method further includes detecting one or more of faults and degradation of the refrigerator based on the power cycle information.

According to some aspects, the method further includes providing targeted communications to consumers having one or more of a predetermined component technology, refrigerator brand, refrigerator model, usage pattern, and refrigerator fault/degradation condition.

Some embodiments involve a system for use with an appliance. The system includes a detector configured to sample power consumption to obtain a power consumption time series having resolution sufficient to extract power cycle information for one or more individual components of a multi-component appliance. An analyzer is configured to extract the power cycle information from the sampled power consumption time series, to compare the power cycle information to stored information of known power cycle characteristics and to classify technology of at least one component of the appliance based on comparison of the power cycle information to the stored information, the analyzer is further configured to generate an output that indicates the technology.

According to some aspects, the analyzer is further configured to use the power cycle information to determine one or more of usage patterns of the appliance, and fault or degradation conditions of the appliance.

According to some aspects, the analyzer is configured to flag facilities for interactions, targeted communications, maintenance, or outreach based on one or more of the technology, brand, model, age, usage pattern, fault condition and degradation condition of the appliance. This may include, but is not limited to, offering by a utility of incentives to recycle old appliances in order to improve overall building efficiency or targeting of advertising to consumers by an appliance retailer.

In some embodiments, a system includes a detector configured to sample power consumption to obtain a power consumption time series having resolution sufficient to extract one or more power cycle parameters for the appliance. The system includes an analyzer configured to extract the power cycle parameters from the sampled power consumption time series, to determine a usage event transient response of the power cycle parameters to a usage event, and to detect one or more of degradation and fault conditions of the appliance based on the usage event transient response, the analyzer is further configured to generate an output that indicates the detected degradation and fault conditions.

### BRIEF DESCRIPTION OF THE DRAWINGS

FIG. 1 is a block diagram of a system in accordance with some embodiments;

FIG. 2 is a flow diagram of a method for determining heat pump characteristics in accordance with some embodiments;

FIG. 3 is a flow diagram of a method in accordance with some embodiments;

FIG. 4 provides a typical refrigerator power time series showing compressor cycles and defroster cycles;

FIG. 5 is a flow diagram of a process of selecting threshold value for extracting refrigerator power cycles from a power consumption time series in accordance with some embodiments;

FIG. 6 is a flow diagram of a method illustrating a process for determining usage patterns of an appliance in accordance with some embodiments;

FIG. 7A is a block diagram illustrating heat transfer in a heat pumping device;

FIG. 7B illustrates a two thermal mass model for a refrigerator;

FIG. 8A is a flow diagram of a method of detecting failure and/or degradation conditions of an appliance in accordance with some embodiments;

FIG. 8B is a flow diagram of a process for detecting refrigerator degradation while controlling for temperature variation;

FIG. 9 is a diagram that illustrates variation of refrigerator compressor duty cycle as a function of ambient temperature;

FIG. 10 illustrates the transient response of a refrigerator after a single door opening event;

FIG. 11 provides graphs of refrigerator data with respect to hour of day; and

FIG. 12 is a graph of experimental data showing duty cycle fraction with respect to ambient temperature.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Some embodiments described herein are directed to systems and methods for determining technology characteristics of a thermostat-controlled cycling appliance, such as a thermostat-controlled cycling heat pump, by analyzing the power consumption of the appliance over time. In various embodiments, the appliance is illustrated by a refrigerator which is an example of a thermostat-controlled cycling heat pump and which may comprise a refrigerator alone, a refrigerator plus freezer, or a freezer alone. It will be appreciated that various concepts discussed herein are applicable to other thermostat-controlled cycling appliances other than refrigerators, e.g., heaters, air conditioners, etc.

According to various embodiments, the appliance technology characteristics that can be identified include characteristics related to the type of operating technology that the appliance uses. Such technology characteristics may include components of the appliance (e.g., water dispensing, icemaking, etc.), technology type of appliance components (e.g., type of compressor and/or type of defroster). Appliances of various brands, models, and ages are associated with certain components and/or component technologies. If the components and/or component technology types of the appliance can be detected, the brand/model and/or age of the appliance may also identified based on the components and/or component technology of the appliance. In some embodiments, the brand/model/age of the appliance is not specifically identified, but the appliance brand/model/age may be determined to be within a certain group of appliance brands/models/ages. For example the analyzer may classify the refrigerator component technology as pre-2010 or post-2010 technology or as pre-2000 or post-2000 technology.

In some embodiments, usage patterns for the appliance may be identified from the power consumption data. According to some embodiments, appliance faults, degradation and/or appliance setpoint information can be determined from the power consumption data. The information derived from analysis of the power consumption data for the appliance can be used, for example, by a consumer to alter their energy use behavior or may be used by a utility service provider to target marketing, education, and/or incentive programs to particular consumers directed to increasing the efficiency of energy use by those consumers. Embodiments discussed herein can be used to make a broad comparison of appliance characteristics between facilities or over time without the time and expense of a manual inspection. Furthermore, the described approaches allow for continuous long-term monitoring of appliance characteristics, facilitating the diagnosis of certain faults and degradations, allowing a monitoring agency to suggest repairs for situations previously identified as having a high probability of success.

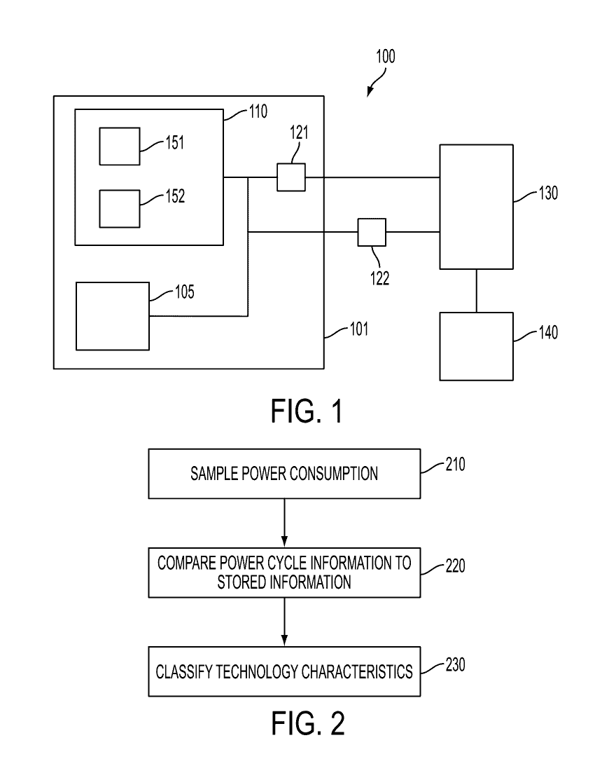

FIG. 1 is a block diagram illustrating an appliance monitoring system 100 for an appliance of interest 110. The appliance 110 may be located in a facility 101 along with other power consuming appliances 105. The facility 101 may be any type of facility, e.g., a private home or apartment, a business or commercial facility. The appliance 110 may include several individual power consuming components 151, 152. For example, in the case of a refrigerator, the individual components 151, 152, can include a compressor, a defroster, an icemaker, a chamber light, etc. One or more detectors 121, 122 are arranged to measure power consumption of the appliance 110 and/or power consumption of the facility, e.g., by periodically measuring the voltage and/or current drawn by the appliance or facility. In some implementations, the power consumption of the appliance 110 may be measured separately from the power consumption of the other appliances 105 using detector 121. In some implementations, the power consumption of all the appliances 110, 105 of the facility 101 are measured in aggregate using detector 122. The power consumption of the appliance may be sampled at intervals shorter than the main thermal time scales of the appliance. For example, the interval between samples may be less than the power cycle durations for the appliance and/or appliance components. The detector 121, 122 can be configured to provide a high resolution sampled power consumption time series by sampling the power consumption of the appliance 110 and/or the facility 101 at a frequency of about 1 sample per minute or at a higher frequency. In some embodiments, the detector 121, 122 is configured to provide a high resolution sampled power consumption time series by sampling the power consumption of the appliance 110 and/or facility 101 at a frequency of about 1 sample per second or a higher frequency.

The appliance monitoring system 100 includes an analyzer 130 configured to analyze the power consumption time series data provided by the detector 121, 122 to determine the various characteristics of the appliance 110, such as technology characteristics. The analyzer may be configured to analyze other appliance characteristics, such as usage pattern, faults, degradation, and/or setpoint. For example, in some implementations, the analysis may include comparing the power consumption time series and/or information obtained from the power time series to stored information, e.g. information stored in a database 140. The stored information can include stored parameter values indicative of appliance technology characteristics (e.g., representative values of parameters such as power cycle amplitude, power cycle duration, periodicity, duty cycle, time between power cycles, etc.) The stored information can also include parameter values indicative of other characteristics such as usage pattern or functional state of the appliance. In some implementations, the stored information may include stored power consumption time series profiles and/or power cycle parameter values or other information from known component technologies, appliance brands/models/ages, etc. The database information can include stored power consumption profiles, parameter values, and/or other information indicative of predetermined usage patterns for the appliance. The database information can include stored power consumption profiles, parameter values, and/or other information indicative of functional state, e.g., degradation or fault states of the appliance.

The analyzer may determine the technology characteristics of the appliance, such as component technologies of the appliance by comparing the stored power consumption profiles, parameter values, and/or other information to the measured power consumption, parameter values and/or other information. Similarly, the analyzer may determine the components of the appliance, the appliance brand, model, and/or age. The analyzer may determine usage patterns of the appliance and/or detect degradation or faults based on analysis of the power consumption of the appliance.

In some embodiments, the analyzer may provide a quantitative measure of appliance energy efficiency using the measured power consumption augmented with some indication of the ambient temperature outside of the refrigerator. The setting of the facility's heating or cooling system, such as a thermostat setpoint, may be a proxy for this temperature. This may also be inferred from outdoor temperature or assumptions about typical indoor temperatures or other more direct measurements. This additional ambient temperature information may also be used by the analyzer to distinguish variation in compressor cycling due to ambient temperature from variation due to other factors.

In some configurations, at least a portion of the detector 121, 122 is located at the facility 101 and the analyzer 130 is located remotely with respect to the detector 121, 122, e.g. at the location of a utility service provider. In these embodiments, the power consumption time series (or data from which the power time series can be obtained) may be transmitted to the analyzer through a wired or wireless data channel. It will be appreciated that other location arrangements for the detector 121, 122 and analyzer 130 are possible. For example, in some arrangements, both the detector 121, 122 and analyzer 130 may be co-located at the facility 101, etc.

Some approaches described herein relate to classifications that can be made from high resolution power consumption data about the characteristics of a refrigerator, including components, component technology characteristics, such as brand/model group, technology type, and other characteristics such as usage pattern or functional state of the appliance. These classifications can then be used by the analyzer to flag particular facilities or consumers to target marketing, education, and/or incentive programs. Such programs would provide information to the facilities and/or consumers that allow the facilities and/or consumers allowing them to reduce energy use or to use energy more efficiently.

In the examples described herein, a refrigerator is generally used as the appliance of interest, however, it will be appreciated that the approaches are applicable to other types of multi-component appliances.

FIG. 2 is a flow diagram illustrating the operation of the monitoring system 100 in accordance with some embodiments. In this and subsequent examples, the appliance of interest is illustrated as a refrigerator. A detector samples 210 power consumption at the power line of the facility or at the power line of the refrigerator at a frequency sufficient to provide a high resolution power consumption time series from which the power cycles of individual components of the refrigerator can be extracted. When the power consumption of the entire facility is sampled, the power cycles of the refrigerator are disaggregated from the power consumption of the facility, e.g., using single tap disaggregation techniques. Single tap disaggregation involves sampling the power use of the entire facility and recording a single aggregate energy use signal. From this single aggregate usage, a disaggregation algorithm separates the portion consumed by the refrigerator.

In some embodiments, the high resolution power consumption time series is obtained by periodically measuring the instantaneous voltage and current at the power line. For example, the sampling frequency (e.g., frequency of voltage and current measurements) may be greater than one sample per minute or greater than one sample per second. Power cycle information, such as one or more parameter values derived from the power consumption time series, is compared 220 to stored information of known power cycle characteristics. Refrigerator technology characteristics such as technology type of the refrigerator components, brand of the refrigerator, model of the refrigerator (or a subset of brands/models), and/or age of group of the refrigerator, can be classified 230 based on comparison of the power cycle information to the stored information.

The process outlined above may be applied to single family homes with a presumption that individual refrigerator power consumption can be monitored separately or disaggregated from total home power consumption, and that the power consumption time series is sufficiently high resolution to observe individual component power cycles (typically with sampling frequency equal or greater than 1 sample per minute). The main components that are of interest for a refrigerator are the refrigerant compressor motor (referred to as a “compressor”) and the frost-free heating circuit (referred to as a “defroster”). For example, estimation of the component technologies, brand/model information and/or age information for a refrigerator can be accomplished by analyzing the regularity of the time intervals between activation of the defroster circuit to distinguish between refrigerators without a frost-free feature (typically the case only for very old refrigerators), refrigerators with a timed defrost feature (moderately old to recent), and refrigerators with a sensor-controlled adaptive defrost feature (limited to relatively new refrigerators). Other refrigerator components such as ice-makers, water dispensers, evaporator fans, and/or chamber lights may also be distinguished with sufficiently high resolution power consumption time series data.

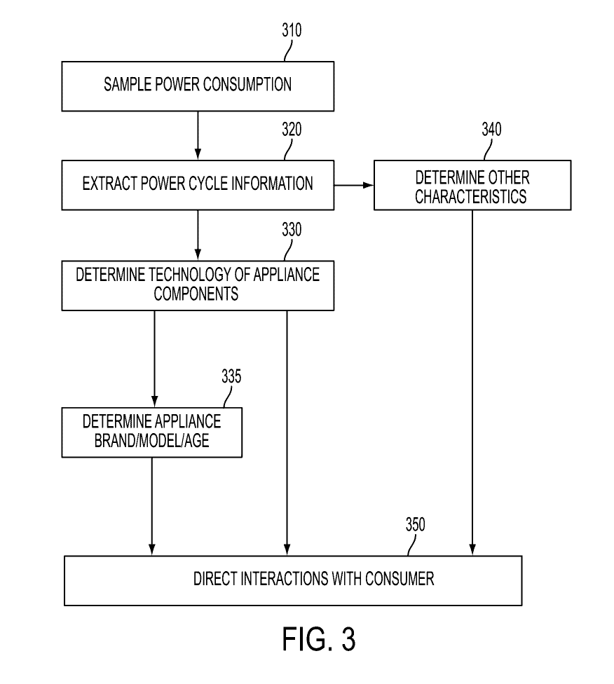

Parameters of the power cycles (on-off cycles) of the refrigerator that are contained in the high resolution power consumption time series can be analyzed to reveal information about the refrigerator technology characteristics, e.g., the technology of the refrigerator components, as well as other refrigerator characteristics, such as usage pattern or fault/degradation conditions as illustrated by the flow diagram of FIG. 3. According to the process illustrated in FIG. 3, power consumption is sampled 310 to provide a power consumption time series as previously described. Power cycle information of the refrigerator and/or refrigerator components is extracted 320 from the power consumption time series. The power cycle information can be used to determine 330 refrigerator component technology characteristics (e.g., the technology type of the compressor and/or defroster). Certain brands/models/age of refrigerators are associated with certain technology components. Thus, once the technology of the components is determined, the brand, model and/or age range of the refrigerator can also be determined 335. In some cases, certain brands and/or models use similar components. Thus the brand or model of the refrigerator may be determined to be within a certain group or subset of brands/models. Other characteristics of the refrigerator, such as usage patterns and/or fault/degradation conditions of the refrigerator, can be determined 340 based on the power cycle information. The refrigerator technology characteristics and/or the other characteristics can be used to direct interactions with consumers 350. For example, the refrigerator technology characteristics and/or other characteristics can be used to determine communications between the owner or user of the refrigerator and some other party that has a vested interest in the refrigerator (such as a company that sells refrigerators or a company that sells the energy that the refrigerator uses) For example, the consumers may receive information suggesting that the consumer consider repairing the refrigerator, purchasing a refrigerator having components with different technology characteristics, and/or changing their pattern of using the refrigerator.

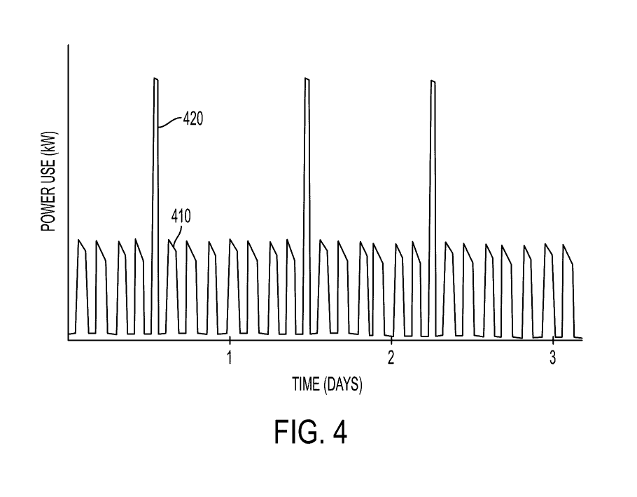

An illustration of the power consumption time series at 1-minute resolution of a refrigerator having a standard vapor compression cycle compressor and periodic cycle defroster is shown in the graph of FIG. 4. A standard vapor compression cycle refrigerator (presently the most common compressor technology type) operates by running the compressor when the interior temperature rises above a setpoint, and turns off when the temperature has cooled below another setpoint. Therefore, the refrigerator's power consumption profile shows pulses 410 in time when the compressor is running; these pulses are referred to as compressor cycles. In order to combat the buildup of frost, a defrosting heating element, e.g., a resistive heater, is periodically used to heat up the interior. When the defroster is on, the defroster heating element is turned on and the compressor is usually turned off, so the power draw of the refrigerator during these times (pulses 420, which are referred to herein as defroster cycles) reflects only the power draw of the defroster. These types of traditional defrosters may cycle periodically with a defroster period (the time between defroster cycles) of 4-48 hours controlled by a timer circuit. Each defroster cycle may have a duration of about 10-20 minutes which is the time the defroster heating element is turned on. More modern systems run the defroster only in the presence of frost, saving energy when the refrigerator is infrequently opened. In the more modern systems, there is a frost sensor, and the defroster cycles non-periodically. Thus, the analyzer may analyze the interval of time between defroster cycles to discriminate between defrosters that rely on a periodic timer circuit and defrosters having a frost sensor.

Some examples for analyzing defroster cycles are illustrated herein, although it will be appreciated that other approaches for cycle analysis may additionally or alternatively be used. The analysis of defroster cycles may rely on the assumption that defroster cycles draw significantly more power than ordinary compressor cycles. Therefore, defroster cycles can be extracted from the refrigerator power cycles by thresholding the power usage, wherein the threshold level of power usage is denoted P_thresh. The analysis may also assume that the defroster cycles last for a fairly well-defined amount of time, characterized by a minimum duration dur_min (e.g., about 3 min) and a dur_max (e.g., about 1 hr) and that the time intervals between defroster cycles is also assumed to be constrained between int_min (e.g., about 3 hrs) and int_max (e.g., about 1 week). The power level during the defrost cycles is expected to be relatively consistent from cycle to cycle.

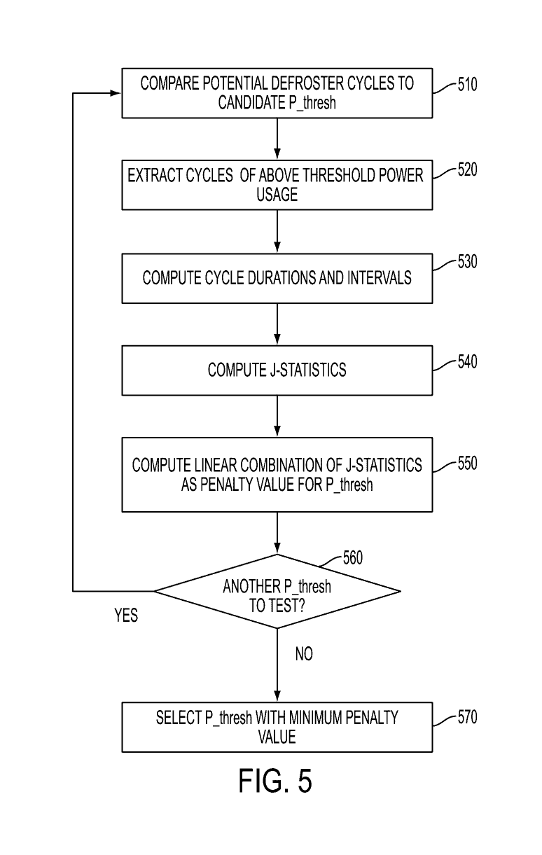

Using these constraints, the periods of time where the power level is above P_thresh can be analyzed and those periods satisfying the constraints are considered candidate defroster cycles. This approach is made more robust by testing multiple values of P_thresh (0.3, 0.4, 0.5, 0.6 kW) and selecting a value of P_thresh. FIG. 5 is a flow diagram illustrating a process of selecting a value for P_thresh. The P_thresh value is selected based on a penalty function which is a linear combination of the relative violations (in L1 norm) of each constraint. Each candidate P_thresh value is tested by comparing 510 potential defroster cycles to each candidate P_thresh. Cycles that are above the candidate P-thresh having continuous above threshold usage are extracted 520. The durations of each cycle and intervals between successive cycles are computed 530. J-statistics, J_int_min, J_int_max, J_min_dur, J_max_dur, are computed for the cycles. The relative min_int violation, J_int_min, is the fraction of intervals between defroster cycles that fall below the expected minimum time and can be expressed:

$$J\_min \_int = \frac{\sum ( cycle\_intervals < int\_min )}{length ( cycle\_intervals )}$$

where cycle_intervals is a vector containing the intervals between all thresholded defroster cycles, and length(cycle_intervals) is the number of intervals between defroster cycles. Note that J_min_int is always in the range [0,1], so the elements in the linear combination are all of equal scaling.

Similarly, the relative max_int violation is the fraction of intervals between defroster cycles that falls above the expected maximum time and can be expressed as:

$$J\_max \_int = \frac{\sum ( cycle\_intervals < int\_max )}{length ( cycle\_intervals )} ;$$

the relative min_dur violation is the fraction of cycle durations that falls below the expected minimum duration and can be expressed as:

$$J\_min \_dur = \frac{\sum ( cycle\_intervals < dur\_min )}{length ( cycle\_durations )} ;$$

and the relative max_dur violation is the fraction of cycle durations that falls above the expected maximum duration and can be expressed as:

$$J\_max \_dur = \frac{\sum ( cycle\_intervals < dur\_max )}{length ( cycle\_durations )} .$$

A linear combination of the J-statistics is computed 550 as a penalty value. The process above 510-550 is repeated 560 for all candidate P_thresh values. The candidate P_thresh having a specified penalty value, e.g., below some predetermined value or a minimum penalty value, is selected 570. Defroster cycles determined by the selected P-thresh may be more likely to be correct.

An equal weighting of all the J-statistics provides satisfactory results.

One practical difficulty occurs because some refrigerator defrost technologies use pulsed defrost. Pulsed defrost cycles are characterized by 1-2 minute dips in power usage (to zero power usage) during the defrost cycle. To account for the possibility of pulsed defrost, the analysis may ignore short (e.g., less than 3 minute) dips below P_thresh.

In some implementations, the output from the defroster cycle extraction for a refrigerator defroster is the set of start times, cycle durations, power levels, and number of dips (for pulsed defrosters) of all defrost cycles. From this set of data, the analyzer determines the intervals between defrost cycles to determine if the defrost circuit is on a timer (characterized by low relative variation in intervals between defrost cycles) or if the defrost circuit is adaptively controlled with a sensor. For example, the equation:

J_adapt_defrost=standard deviation(diff(start_times))/mean(diff(start_times)),

where start_times is a vector of starting times of all extracted cycles and diff(start_times) is a vector of all the time intervals between start_times, may be used to discriminate between adaptively controlled or periodically controlled defrost technology. J_adapt_defrost is expected to be small (<0.1) for timed periodic defrost circuits, otherwise the defroster is determined to be adaptively controlled. In some embodiments, the analyzer may be configured to calculate J_adapt_defrost calculated from the power consumption time series and to compare the calculated value J_adapt_defrost value to a stored threshold value (e.g., less than about 0.1). If the calculated J_adapt_defrost is less than the threshold, the analyzer determines that the defroster technology is timed defrost. Alternatively, if the calculated J_adapt_defrost is greater than or equal to the threshold, the analyzer determines that the defroster technology is adaptively controlled.

The number of dips in the defroster power cycle can be used to determine the presence of a pulsed circuit. To determine whether the defroster includes a pulsed circuit, the analyzer may determine the number of dips in the defroster power cycle and compare that number of dips to a stored threshold.

A refrigerator compressor cycle is characterized by a characteristic power level, e.g., about 100-150 Watts in a typically-sized modern household refrigerator in the United States. Vapor compression technology (the most common) exhibits a sharp spike in energy use when the cycle starts due to pressure equilibration along the refrigerant line. Typically, during the cycle, the energy use decreases with time as the vapor fraction along the refrigerant line changes.

These cycles therefore have a characteristic shape that can be extracted and identified by pattern matching—e.g., sample by sample, comparison of the compressor power cycle extracted from the power consumption time series to a known power cycle pattern that is representative of a known compressor technology. The identification of compressor technology can be complicated by recent developments in compressor technology including variable speed compressors, and multiple evaporator technology. In the case of variable speed compressors, the power level exhibits a stepped temporal profile as the compressor motor speed is adjusted up or down. These adjustments manifest as a sharp step with an exponential convergence towards a quiescent power level. The individual steps are all similar in shape and may be extracted by matching against this pattern.

Multiple evaporators in a refrigerator may be included to better control the temperature of the freezer and fresh-food compartments individually. Some refrigerators contain a refrigerant switch that controls which evaporators are in use. The power consumption characteristics for multiple evaporator refrigerators (in the absence of a variable speed compressor) are the superposition of two pulse trains, each of which would be characteristic of a single vapor compression circuit. These individual pulse trains can be extracted using pulse extraction techniques. The extracted pulse trains may each be matched to known characteristic shape profiles indicative of a vapor compression component.

In addition to the compressor and defroster, additional refrigerator components contribute to the power consumption temporal profile of the refrigerator. For instance, many refrigerators feature built-in icemakers, water dispensers, and ice crushers. When used, these components typically do not draw power for more than 1 minute, and are characterized by sharp spikes in the power usage. Individual spikes of duration less than approximately two minutes can be attributed to these components. The extraction of these spikes may be performed and the refrigerator components may be identified before any other cycle extractions since the extra spikes contaminate the data with high frequency noise.

Because refrigerator components such as the compressor or defroster operate within well-defined power levels, classification of the refrigerator state (whether the compressor, defroster or other components are running) can be determined. From this state classification, the intervals between defroster activation can be determined, and the variation of the intervals computed. For example, as previously discussed, the presence of a pulsed defroster circuit is recognizable due to a series of dips present in the power consumption, and is characteristic of particular refrigerator models manufactured within a specific timeframe. A similar analysis is extended to the compressor cycles, where the technology of the compressor (e.g. vapor compression, characterized by a tall initial spike when the compressor turns on, and variable speed compressors, having dynamically changing power levels of the power cycles) can be determined.

The temporal characteristics of the power consumption of the refrigerator indicate the technology of particular components of a refrigerator. These characteristics may also be used to infer brand or model of the refrigerator or to infer an approximate age for the refrigerator and/or an approximate readiness for recycling. These techniques can be generalized by matching one or more characteristics of the power consumption time series to a set of known power consumption characteristics of various known refrigerator models. Thus, the details of the power consumption over time can be used to classify the refrigerator model and/or brand. In some cases the details of power consumption over time can be used to classify the refrigerator model and/or brand as belonging to a subset of refrigerator models and/or brands. For example, certain models of refrigerators exhibit characteristic step-like power variations when the compressor is on due to a variable speed compressor. The magnitude and duration of the steps can be extracted and compared to a database of known parameters to infer the refrigerator model.

In some embodiments, the analyzer may be configured to use the measured power consumption time series to determine characteristics of the refrigerator other than the technology characteristics. For example, statistical analysis of the power cycles can be used to infer various appliance characteristics.

In some embodiments, these non-technology characteristics identified by the analyzer can include, for example, a usage pattern of the refrigerator. As one example, the variability in power cycles due to usage provides an indication of the load on the refrigerator. According to some implementations, usage patterns can be determined by analyzing the variation in compressor power cycle amplitudes, durations, frequency, and/or duty cycle. Additionally or alternatively, usage patterns can be determined based on frequency of defroster cycles in refrigerators with adaptively controlled defrost circuits. The adaptively controlled defrost cycles depend on the number and duration of door openings.

In some implementations, the variability in compressor cycle durations can be measured throughout a day by computing cycle-time variations, e.g., hourly or half-hourly, over many days, e.g., 30, 60, or 90 days to obtain a usage profile indicative of users' daily routines. For example, high variation might be expected at breakfast and supper times when refrigerator usage is high.

Averaging over particular days of the week allows isolation of usage profiles over the week (for example to compare weekday and weekend usage). The variation of cycle times over a year provides insight into seasonal variation of usage.

The variation in the refrigerator parameters that depend on number and duration of door openings can provide an indication of particular kinds of use of a refrigerator when analyzed over periods of time. Examples of refrigerator parameters that depend on use include compressor cycle amplitude, compressor cycle duration, interval between compressor cycles, and interval between defroster cycles for adaptively controlled defroster circuits. Inference of usage patterns can be performed by binning at least one of these refrigerator parameters into time bins over a period of time, e.g., hours, days, weeks, or months. The variation of the parameter is computed, for example, by calculating the standard deviation of the parameter for each time bin. The variation of the parameter within each bin is an indication of the degree of usage within the period of the bin. Periods of higher variation correspond to periods of higher usage. The variability in the parameter, e.g., compressor cycle duration, can be measured throughout a day by computing hourly cycle-time standard deviation over many days to obtain a user profile indicative of a user's daily routines. For example, high variation might be expected at breakfast and supper times. In some embodiments, a mean or median of each time bin is used as an indication of the degree of usage, with higher values corresponding to higher usage.

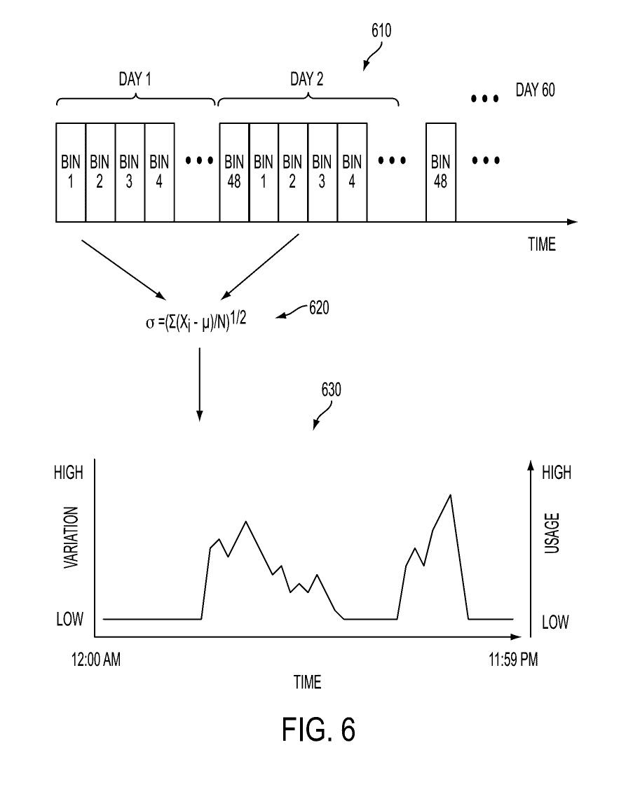

FIG. 6 is a flow diagram that illustrates a process of determining usage patterns based on analyzing variation in refrigerator parameters wherein each bin is one half hour (30 min bins), and the parameter (e.g., duration of each compressor cycle) is binned 610 in one of 48 bins corresponding to the time of day that compressor cycles occur throughout the 24 hour day for a time period, e.g., 60 days. This analysis can be varied by selecting different bin sizes and/or different times for the bins from which samples are taken. The variation 620 of the parameter samples in each bin over the time period is computed, e.g., by calculating the standard deviation as shown in FIG. 6:

$$σ = \sqrt{\frac{{X}_{i} - μ}{N}} ,$$

where Xi is the i^{th} parameter sample in the bin, e.g., compressor cycle duration, μ is the mean of the sample values of the bin, and N is the number of samples in the bin. The variation is correlated to usage, wherein high variation indicates high usage and low variation indicates low usage. The graph 630 shows an example of a daily usage pattern that may be determined by the analyzer using this process.

As mentioned previously, the process outlined above can be used to observe differences between weekday and weekend usage patterns. For example, the analysis can be performed by separately analyzing cycles on weekdays and weekends, comparing the differences in the variation (and thus the usage patterns) during weekdays and weekends. Similarly, differences in seasonal usage can be determined.

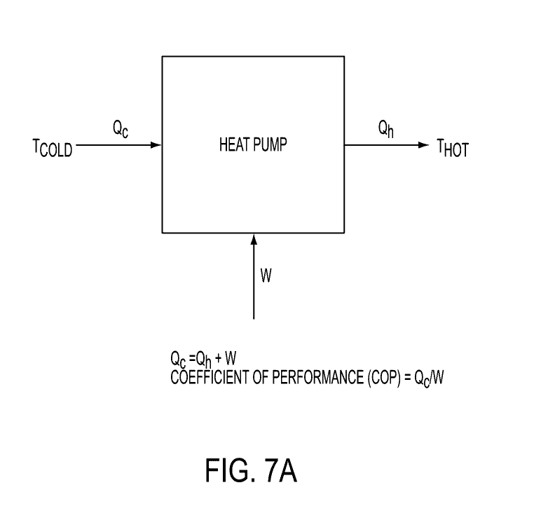

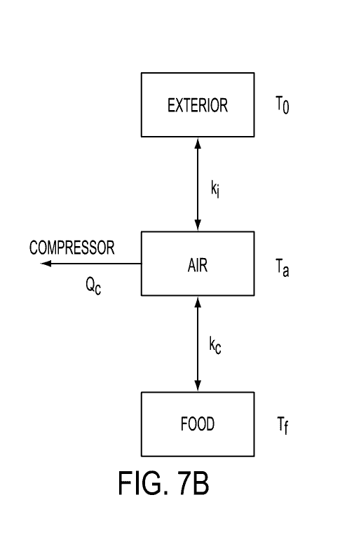

FIG. 7A illustrates the operation of a heat pumping device. The heat pump takes thermal energy, Q_{c}, from the colder environment at temperature T_{c} and transfers thermal energy, Qₕ, to a warmer environment at temperature Tₕ. The work per unit time, W, is needed to operate the heat pump so that in cooling mode, Q_{c}=Qₕ+W. The coefficient of performance of the heat pump in cooling mode is COP=Q_{c}/W. Those skilled in the art will appreciate that heat pumping devices may be operated in cooling mode to cool an area or in heating mode to heat an area.

A refrigerator, which is a specific example of a heat pump, works to keep the air inside the refrigerator within a specified temperature band. In order to maintain the cool interior temperature, the refrigerator compressor will run more when there is a larger heat load on the refrigerator. Sources of heat include conduction through refrigerator case and infiltration of outside air through leaks in seals or through an open door, when the temperature outside the refrigerator is warmer than the temperature inside; and heat from food and other items that are added to the refrigerator when they are at a temperature warmer than the temperature of the air in the interior of the refrigerator. Additionally, the temperature of the air outside the refrigerator, cleanliness of the evaporator coils, or other environmental parameters may affect the instantaneous power draw of the refrigerator cooling system. Thus, parameters such as the refrigerator compressor cycle duration and duty cycle are affected by factors including the ambient temperature exterior to the refrigerator, the cooling load due to content in the refrigerator that is at an elevated temperature when added to the refrigerator), and the frequency of door openings. Whereas the frequency of door openings can be related to user demands for the refrigeration, changes in ambient temperature may present a confounding factor with respect to refrigerator cycling patterns as it also causes increased power consumption while not being as directly related to user demands for refrigeration. These and/or other confounding factors may obscure the usage pattern analysis. In some embodiments, the analysis of the variation in the compressor cycle durations and duty cycles to determine refrigerator usage is performed over periods of time where confounding factors (such as ambient temperature) are relatively equal or are accounted for in the usage pattern analysis based on assumptions or knowledge about the local environment and refrigerator usage. For example, ambient temperature variations may best be determined by analyzing the power cycles early in the morning, when door openings are expected to be infrequent and refrigerator contents are expected to be close to the temperature of the air in the refrigerator, so variations in compressor power cycles are likely due only to the ambient temperature exterior to the refrigerator.

A refrigerator may be modeled by a two thermal mass model, illustrated in FIG. 7. The two masses are the cold air and the food contents within the refrigerator. It is assumed that the food interacts thermally only with the air through conduction and convection, and that the action of the refrigeration cycle acts to remove heat from only the air. The governing equations for the food and air within the refrigeration compartment can be written as:

mₐ\dot{T}ₐ=kᵢ(T₀−Tₐ)+k_{c}(T_{f}−Tₐ)−\dot{Q}_{c} (1)

m_{f}\dot{T}_{f}=k_{c}(Tₐ−T_{f}), (2)

where mₐ and m_{f} are the thermal masses (J/K) of the air within the refrigeration compartment and the food, respectively, kᵢ is the effective thermal conductance (Watts/K) through the walls of the refrigeration chamber, k_{c} is the effective thermal conductance that characterizes the heat exchange between the food and the air due to convection and conduction, Tₐ is the temperature of the air in the refrigerator, T₀ is the ambient temperature exterior to the refrigerator, T_{f} is the temperature of the food within the refrigerator, and \dot{Q}_{c} is the cooling power (W) supplied by the refrigerator compressor. This is a simplified model and radiation and the thermal mass of the refrigerator itself are either ignored or incorporated into the effective quantities described above.

The energy balance in a refrigerator is considered by integrating Eq. (1) and Eq. (2) over a cycle. Assuming that the interior air temperature at the beginning of the cycle is equal to the interior air temperature at the end of each cycle and that the interior air temperature is close to the setpoint Tₛₚ and varies only a small amount during the cycle (e.g. within a deadband of 1-2° C. under bang-bang control), we can integrate Eq. (2) from time t=0 at the start of the cycle to t=t_{c} at the end of the cycle to obtain

T_{f}=Tₛₚ+[T_{f}(0)−Tₛₚ]e^{-α}^{_{f}}^{t} (3)

With similar assumptions about the cycle-variation of the air temperature, the mean electrical power draw of the compressor P over the time that the compressor is on can be related to the compressor duty cycle D, the coefficient of performance of the heat pumping system (COP), and the cycle-average cooling power of the system [symbol] \dot{Q}_{c} [symbol] by integrating Eq. (1) over one cycle:

$$\begin{matrix}〈 {\dot{Q}}_{c} 〉 = \frac{C O P}{{t}_{cycle}} \int P d t \\ = D \times P \times C O P \\ = {k}_{i} ( {T}_{0} - {T}_{sp} ) + {k}_{c} ( 〈 {T}_{f} 〉 - {T}_{sp} )\end{matrix} \qquad ( 4 )$$

Under equilibrium conditions when T_{f}=Tₛₚ, the duty cycle and ambient temperature difference are related by

$$D = \frac{{k}_{i}}{P \times C O P} ( {T}_{0} - {T}_{sp} ) \qquad ( 5 )$$

The constant of proportionality

$$\frac{{k}_{i}}{C O P}$$

is an inverse measure of the overall efficiency of the refrigerator system: more effective thermal insulation reduces kᵢ and the COP is a measure of a high performance cooling system. A more efficient refrigerator in this context has a cooling system with a higher COP and has better insulation (lower kᵢ). Thus, if the assumptions stated here are appropriate for a refrigerator, the duty cycle is expected to show a primarily linear relationship to the exterior temperature (or to the difference between the exterior temperature and the interior air temperature), with a shallower slope corresponding to a more efficient refrigerator. The inverse of this slope can be considered a figure of merit for a refrigerator.

A similar analysis can be applied to other thermostatically-controlled cycling heat pumps, with appropriate reversals in signs for systems where the hot side (rather than the cold side) is the controlled environment and where the loads on the system may be heat sinks rather than heat sources. Furthermore, a similar analysis can be applied to thermostatically-controlled cycling appliances that are heaters without being heat pumps (such as furnaces and water heaters), with appropriate choices of signs for the conduction load and other loads and appropriate definition of the heater efficiency rather than the coefficient of performance.

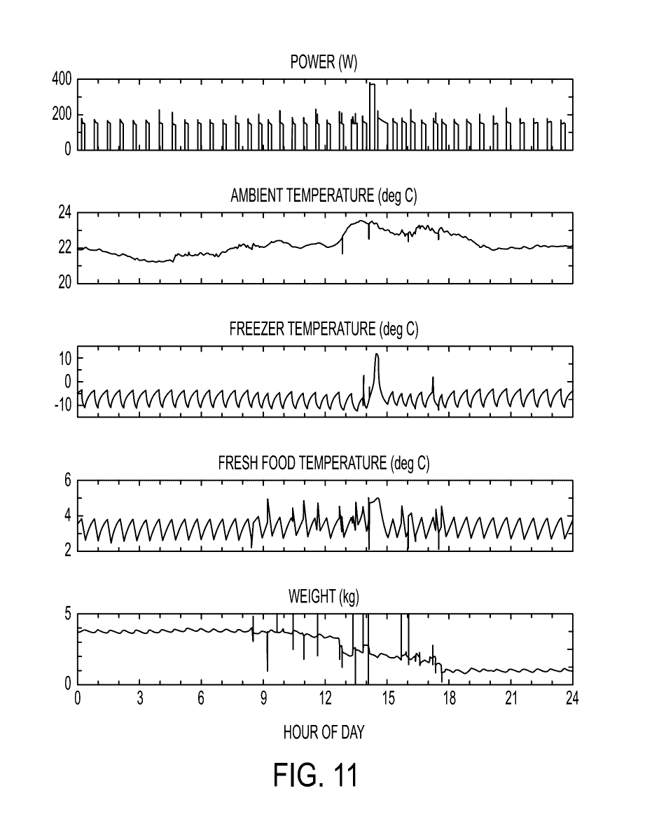

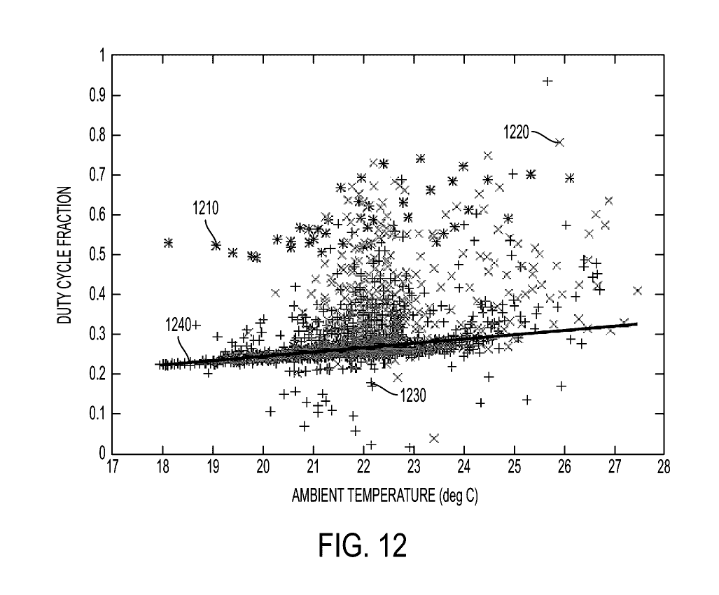

In deriving Eq. (5) from Eq. (4), the conduction term from the food was ignored. This is only accurate under equilibrium conditions. For example, immediately after warm food is added to a refrigerator, the conduction term is positive, leading to values of η greater than Eq. (5) would predict. Such added cooling load events cause deviations from equilibrium behavior that last multiple compressor cycles because the thermalization time scale of added warm contents is typically much longer than the average cycle time. This separation of time scales allows the figure of merit described above to be robustly extracted. The applicability of this model has been experimentally verified as discussed below with reference to FIGS. 11 and 12.

The figure of merit can be extracted with knowledge or assumptions about the exterior and interior temperature of a refrigerator in addition to the time series information about the cycling of the cooling system. The interior temperature may be inferred from industry standards, assumed to be constant, drawn from a connected refrigerator that reports this value, or from some other source of information. The exterior temperature may be assumed to be proportional to the outdoor temperature; it may be measured by a thermostat or thermometer and reported either by a connected thermostat or a person or device that reads the thermostat or thermometer. The exterior temperature may also be extracted from the average power draw of the cooling system, under a model or understanding of how the instantaneous power draw of the cooling system varies with temperature. (Such variation is not included in the analysis above). This figure of merit may be used to compare one refrigerator to other refrigerators or to a baseline or standard in order to classify or label the refrigerator based on its overall efficiency.

Some embodiments involve analyzing the measured power consumption time series of the refrigerator to detect fault and/or degradation conditions. In general, the terms “fault” and “degradation” refer to anomalies in refrigerator conditions that lead to sub-optimal operation. The term “fault” is used to refer to a change that occurs over a relatively short period of time and the term “degradation” is used to refer to changes that occur over a relatively long period of time. Fault conditions (such as a sudden development of a refrigerant leak) are marked by relatively sudden changes in power cycle characteristics. Degradation conditions (such as accumulation of dust on evaporator coils or deterioration of insulation) may exhibit long term, gradual changes in power cycle parameters which can be typically monotonic. Both these kinds of conditions may be observable from the extracted power cycle parameters of the refrigerator. The power consumption of the compressor when it is on is not expected to vary significantly under normal operations. Any gradual increases over time in power consumption could indicate degradation in the vapor compression system. On the other hand, sudden changes are typically acute symptoms, which can result from causes such as compressor pump or motor failure or refrigeration line leaks. Sudden changes associated with faults can be detected based on a relatively short time scale operational baseline for comparison and longer term changes, e.g., degradation can be detected based on a longer time scale operational baseline.

The analyzer may detect long time scale variation of power consumption characteristics (such as lengthening compressor on-times, other factors being relatively equal) to provide an indication of refrigerator fault or degradation conditions such as reduced condenser coil efficiency (possibly due to dust buildup), poor door seals, deteriorating insulation, or failing motors. Such an analysis may involve a combination of information from long time scales (over years) with information on extremely short time scales (power cycle transients detectable over minutes or seconds). The combination of long time scale information with short time scale information can occur in several ways. For example, the long time scale information can be used to establish a baseline of performance, while short time scale events such as a sudden jump in an operating parameter (such as power consumption during a cycle) compared to the baseline indicates a sudden fault condition.

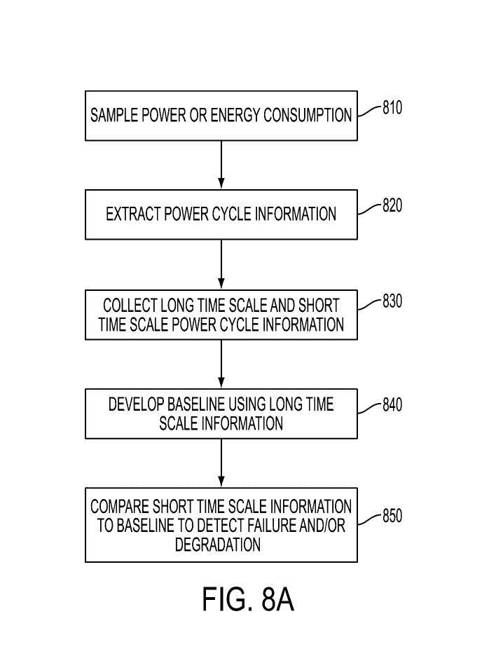

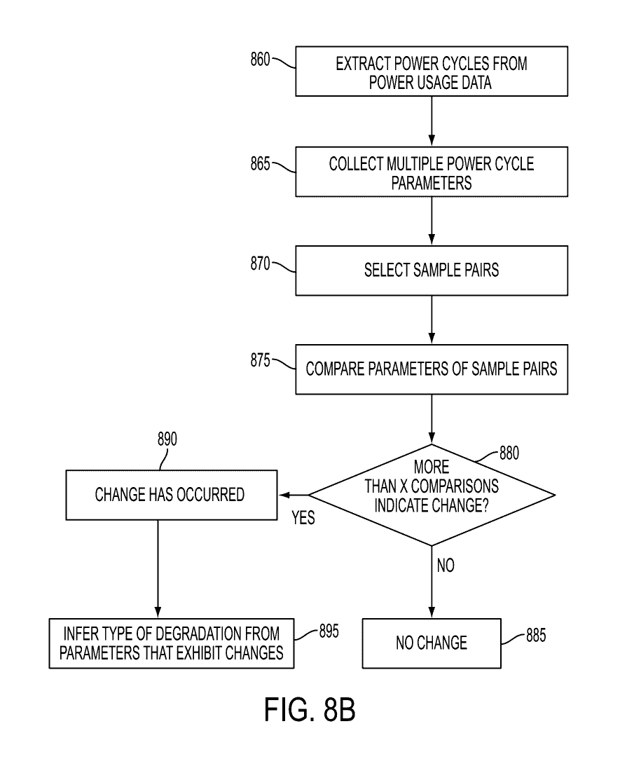

For example, increases in average cycle times or decreases in average power when the cooling system is running may indicate a change in the operation of the refrigeration system. Such a change may, for example, be due to degraded refrigeration system efficiency. For example, the cooling power of the cooling system may be reduced while the thermalization time (insulation) stays the same. Lower on power can also occur under certain refrigerant leakage scenarios. The exact cause of the degradation may not always be inferable from this type of power cycle data, but certain causes can be observed. For example, the extremely short time transient power dynamics when the compressor turns on (specifically, turn-on time) provides an indication about the health of the compressor, with shorter turn on times indicating a compressor in better condition. The analyzer may compare the measured turn-on time of the compressor and/or the rate of change of the compressor turn-on time to one or more stored thresholds of the same compressor or other known compressor models and provide a relative health of the compressor based on the analysis. For example, this analysis yields a quantitative measure, in the form of a ratio of times, of the relative health of the compressor over time if stored thresholds from its own operating history are used for comparison. FIG. 8A is a flow diagram illustrating a process for detecting failure and/or degradation of an appliance. The power/energy consumption is sampled 810 at a sampling frequency sufficient to extract 820 power cycle parameters for one or more individual components of the appliance. The analyzer detects 830 power cycle parameters over a long time scale and develops 840 a baseline of power cycles for the one or more components. The analyzer also detects 830 power cycle information over a short time scale. The analyzer compares 850 the short time scale power cycle information to the baseline to detect fault and/or degradation of the appliance.

Monitoring of power cycles over time-scales of a year or more allows comparison of operating characteristics under similar ambient conditions to control for weather variation to facilitate detection of gradual degradation. FIG. 8B is a flow diagram of a process for detecting refrigerator degradation while controlling for variations in the exterior ambient temperature and/or humidity that may be related to the outdoor temperature and/or humidity. The power usage of the refrigerator is monitored 860 over a long time scale, e.g., more than one year, and power cycles are extracted from the power usage. Multiple power cycle parameters, such as power level, duty cycle and/or duration for each compressor cycle, are determined 865 from the power cycles and are stored. A number of sample sets are selected 870 for comparison, e.g., about 1000 sample sets, each sample set including multiple days of collected data. For example, each sample set may comprise two days selected approximately one year apart to control for seasonal variations in operation conditions and user behavior. Due to the possibility of correlation between weather parameters and the indoor ambient conditions of a refrigerator, the two selected days may be selected such that weather parameters on the two days are approximately the same, e.g., same temperature, humidity, cloud cover, etc.

The power cycle parameters for the sample sets are compared 875. Comparison of the power cycle parameters may indicate a change in the operating characteristics of the refrigerator. Such changes may be due to changes in user behavior or degradation, e.g., power consumption is increasing over time, duration of power cycles and/or duty cycle of power cycles are increasing over time, etc. If less than a predetermined number or fraction of the power cycle parameter comparisons indicate a change in operating characteristics 880, then the analyzer determines that no or minimal changes have occurred 885. However, if the number or fraction of power cycle parameter comparisons that indicate change is greater than or equal to the predetermined number or fraction, the analyzer determines that significant change in the operating characteristics has occurred 890. In some embodiments, all such changes may be assumed to be caused by gradual degradation. Gradual degradation may be due to a number of different causes, e.g., door seals cracking, compressor failure, etc. The analyzer may determine 895 the cause of the degradation based on the particular parameter degradation. In some implementations, to determine the particular degradation cause the analyzer may retrieve and process higher resolution parameter data than that used to identify the degradation.

In some embodiments, the analyzer may use known power cycle fault and/or degradation profiles for various technology types, brands and/or models of refrigerators stored in a database or elsewhere to provide early detection and/or identification of fault and/or degradation conditions of the refrigerator. For example, a refrigerator of a particular technology type, brand, and/or model may have previously been identified as having experienced certain types of fault and/or degradation. The power cycle profile indicative of that fault/degradation can be stored in the database. Subsequently, if a refrigerator is identified as the particular technology type, brand and/or model, the analyzer may compare the power cycle profile of the refrigerator to the known fault/degradation profile. This process may provide for an early indication of fault/degradation conditions, allowing for repairs and/or maintenance to be initiated before more serious failure occurs.

Under normal operation, variation in compressor power levels is expected to primarily result from changes in ambient temperature. Therefore, these long time scale variations can be combined with analysis in the ambient temperature exterior to a refrigerator (which is likely interior to a building) to provide a more accurate view of refrigerator performance. If the refrigerator is housed in a building with indoor air temperature controlled by a heating and/or air conditioning system, the indoor air temperature may be inferred by estimating the setpoint from an analysis of air conditioning or heating duty cycles along with weather data as described in commonly owned patent application Ser. No. 14/228,207 filed Mar. 27, 2014 which is incorporated by reference herein in its entirety. The setpoint analysis as described in the Ser. No. 14/228,207 application determines an “effective-setpoint” for the interior of the house.

Information about or inference of the air temperature exterior to the refrigerator can be used to improve classification of the refrigerator brand and/or model and/or other technology characteristics of the refrigerator. In some implementations, the power usage of the refrigerator is determined by measuring power cycle parameters of the refrigerator as a function of temperature as indicated by the effective-setpoint or by some other indication of the exterior temperature. The refrigerator brand and/or model can be matched or narrowed down by comparing the power cycle parameter information as a function of temperature with a database of known refrigerator characteristics.

In some implementations, the effective-setpoint varies with time and is an indicator of ambient temperature. Thus, the effective-setpoint can be used as an input to the refrigerator usage analysis previously discussed. The indoor air temperature may also be directly measured and reported by a thermostat or other device and such assessment may equally be an input to the refrigerator usage analysis.

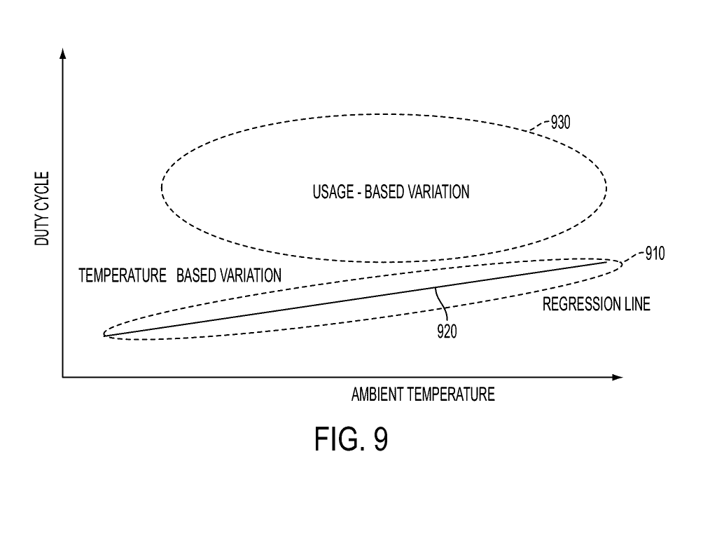

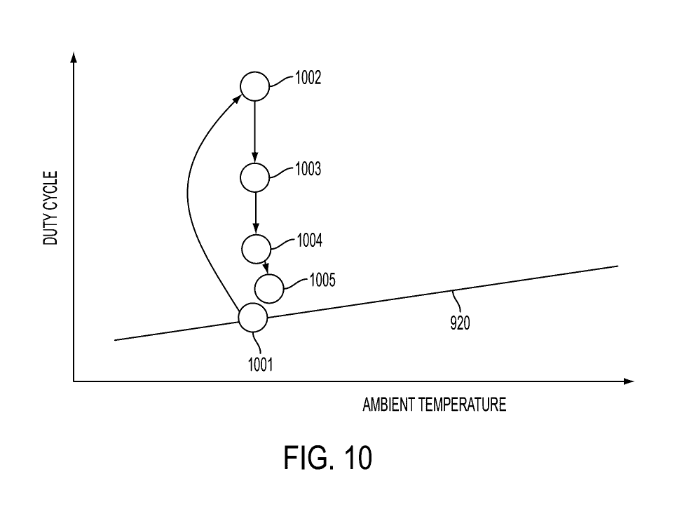

Changes in the transient response of the refrigerator indicated by the compressor power draw over a small number of power cycles (typically less than 10) can be used to infer the degradation of the refrigerator door seals and/or other faults and degradations. FIGS. 9 and 10 illustrate transient analysis of compressor cycles. FIG. 9 is a diagram that illustrates how refrigerator compressor duty cycle varies as a function of ambient temperature. For example, when the refrigerator door is not opened and the contents of the refrigerator are unchanging and at thermal equilibrium, the duty cycle varies relatively gradually and almost linearly with ambient temperature as shown in area 910 of the diagram along regression line 920. This is in the case where the changes in the COP due to changes in ambient temperature are small. However, cycles that follow usage events (door openings and/or changes in loading) are characterized by upward deviations from the regression line 920 and fall into area 930 of the diagram. This pattern is also evident in the experimental data obtained from the example as shown in the graph of FIG. 12.

Transient response of refrigerator power cycle parameters following events such as usage events and/or defrost events can be used to determine degradation of the refrigerator and/or refrigerator components. FIG. 10 illustrates the transient response of a refrigerator after a single door opening event. Each data point 1001-1005 represents one compressor cycle. Prior to the door opening event, the duty cycle data point 1001 falls near regression line 920. Data point 1002 represents the first compressor cycle after the door opening event. The door opening event causes the first compressor cycle after the door opening event to be long because the warm air that entered the refrigerator while the door was open increased the heat load on the system. Due to the heat capacity in different components of the refrigerator, the way that internal temperature is measured and controlled in the system, and other physical effects of the system and its controls, it may take multiple compressor cycles before the duty cycle returns to a steady state value near the regression line. Data points 1003-1005 represent the duty cycles for the second, third, and fourth compressor cycles following the door opening event, showing that the duty cycles progressively decrease following the event.

The analyzer may determine the transient response of the refrigerator as described above with reference to FIGS. 9 and 10 and track changes in the transient response over time. The changes in the transient response can be used to detect refrigerator faults and/or degradation. For example, if the analyzer determines that the transient response after a use event and/or after defrost event indicate recovery times that are slower than expected, the analyzer may detect a fault or degradation condition, e.g., door seals cracking or other problems.

Using one or more of analyses described herein, the analyzer may be configured to generate an output that flags potential facilities for targeted communications or outreach based on one or more of the technology, brand, model, age, usage pattern, and fault or degradation conditions of the appliance. For example, a utility service provider can select a group of homes or facilities to receive incentives communicated to the home or facility electronically or otherwise related to reducing appliance energy consumption (for example, offering refrigerator recycling rebates). For example, the utility may select homes with refrigerators lacking a defroster, or may select homes with timer-controlled defrosters, as these typically indicate old refrigerators. Alternatively, the utility may use this analysis to preclude a group of homes from receiving incentives (for example, to preclude homes with very new or efficient refrigerators from receiving new refrigerator purchase rebates. After offering such incentives or other communications or outreach, the same analysis can be used for the targeted homes to evaluate the effectiveness of the energy efficiency programs.

Embodiments discussed herein can be used to make a broad comparison of refrigerator characteristics between facilities or over time without the time and expense of a manual inspection. Furthermore, the described approaches allow for continuous long-term monitoring of refrigerator characteristics, facilitating the diagnosis of certain refrigerator faults and degradations, allowing a monitoring agency to suggest repairs for situations previously identified as having a high probability of success.

In addition to compressor and defroster cycles, evaporator fans, ice-makers, water/ice-dispensers, and interior lighting cycling can also be monitored and analyzed for frequency of use and refinement of refrigerator characteristics.

The characteristics of the refrigerator component power consumption at high resolution (e.g., less than 1 minute or less than one 1 second) typically show short-time-scale variations which may be characteristic of certain brands and/or models of refrigerators. Thus measured power consumption data can be compared against known characteristics to narrow down the technology characteristics of the refrigerator, including the component technology, the age, brand and/or model of the refrigerator and/or refrigerator components. Mini-fridges, freezers, and combined refrigerator/freezer units may also be distinguished based on specifics of their temporal power cycle profiles.

The analysis presented above need not be specific to vapor compression refrigeration systems. Similar analysis can be applied to alternative refrigeration systems such as ammonia, carbon dioxide, or thermoelectric based systems. In general, any appliance with cycling behavior, e.g., wherein the control mechanism is based on a thermostat that cycles a component that draws energy to drive the thermodynamic cycle, can be analyzed according to the approaches discussed herein.

Furthermore, the analysis above need not be specific to household appliances. Industrial and commercial systems can also be monitored. In particular, fault and anomaly detection based on high resolution power consumption represents a low cost and minimally intrusive monitoring scheme.

According to approaches discussed herein, various aspects of appliances such as a refrigerator can be determined using only power consumption data without requiring a manual inspection within the home or facility. For example, technology characteristics of a refrigerator that can be determined include compressor technology, defroster technology, refrigerator features (e.g. icemaker), a set of possible brands/models of the refrigerator, approximate age of the refrigerator. Additionally, other characteristic of the refrigerator may be detected such as fault and/or degradation conditions and usage patterns. Some of the analysis may be performed without reference to predetermined power levels and instead rely on the time when cycle activation events occur. This makes it easier to apply to potentially inaccurate data from single-tap disaggregation since, for example, defroster spikes can be seen clearly in poorly disaggregated data where it may not be possible to extract an accurate refrigerator-only time series. The analysis discussed herein may go beyond the simple question of which refrigerators use more energy, and attempts to provide a reason for higher refrigerator energy usage. Since older and faulty refrigerators tend to use more energy, this method provides a heuristic for a utility or other monitoring party to targeting incentive and rebate programs to households which could benefit the most.

Implementations described herein include methods for remotely inferring characteristics about an appliance from high resolution power consumption data, wherein the sampling rate (typically greater than or equal to 1 min resolution) of the power consumption allows for the power cycles of individual appliance components to be resolved with sufficient accuracy. The high resolution data may be obtained by disaggregating the appliance power consumption data from the power consumption of a facility or may be obtained from detector dedicated to monitoring the power consumption of the appliance of interest. For analysis based on the duty-cycle alone (such as the efficiency metric), the relevant information may be obtained by any monitor of when the cooling system of the refrigerator turns on and off; this information could be obtained by measuring electrical current alone, for example, or even from an accelerometer on or acoustic sensor that monitors a motor on the cooling system.

Short time-scale (on the order of minutes) power variation can be used to classify the brand/model of a refrigerator. Long time scale power use monitoring (on the time scale of years) allows estimation of the functional state (e.g. fault or degradation detection) of the refrigerator. Medium time scale (on the order of days) variation can be used to reveal consumer usage patterns (e.g. frequency and variation of loading over time). Sensitivity to changes in the temperature external to the refrigerator (which may be obtained through external means) can reveal information about the overall efficiency of the refrigerator including quality of refrigerator insulation and seals.

Based on the analysis, energy efficiency or marketing programs can be targeted to consumers with reference to the particular characteristics of their appliance. For example, the energy efficiency programs for a refrigerator may include rebate/recycling offers based on approximate age of the refrigerator, marketing offers for energy reduction products, and/or educational offers for improving usage behavior targeted to high-use consumers identified by the analysis.

### Example

A refrigerator (Roper model RT18DKXKQ05) was instrumented with power, temperature, and load cell sensors. Data from all sensors were captured every 5 seconds and logged. The refrigerator was plugged into an energy monitor (modified Kill-A-Watt® meter) that provided the output voltage and current signals to an analog-to-digital converter (ADC, Measurement Computing USB-2416-4AO). The instantaneous power was computed at 550 samples per second every 5 seconds and time averaged to obtain the average power consumption. Note that the voltage waveform is very nearly a pure sinusoid, while the current waveform is far less regular. Due to sampling device limitations, the voltage and current were sampled alternately in leapfrog fashion, and so the samples never correspond to the same time point. In order to remedy this, the voltage waveform is first fit to a sine wave function, and the voltage values at the current time points are interpolated using this fit in order to compute instantaneous power.

Temperature sensors (Analog Devices TMP36) were wired to the ADC and supplied with a+5V rail with decoupling capacitors. The sensors were taped to the interior of the fresh food and freezer compartments, and signals brought out using flexible ribbon cables to maintain a proper door seal.

In order to track changes in the refrigerator contents, a custom platform weigh scale was placed underneath the refrigerator and the total weight was logged.

The refrigerator data was logged in several contiguous time periods four 5 months. A plot of a small portion of the data is shown in FIG. 11. The compressor and defrost cycles are clearly visible from the power consumption traces. In addition, due to the fresh food compartment light bulb (60 Watts), door opening events are also easily detectable, and further corroborated by the load cell signals. By extracting and classifying all the cycles, a plot of the duty cycle fraction with respect to ambient temperature can be produced to assess the model in Eq. (5).

FIG. 12 shows such a plot, where each point represents one compressor cycle. A set of data points 1210 are cycles immediately following a defrost event, points 1220 are cycles immediately following a door opening event, and points 1230 are all other cycles. The cycles 1230 that do not immediately follow a change in the thermal load from a door opening or a defrost event are expected to be times when the system is closer to equilibrium. These cycles show a very strong linear correlation between the duty cycle and the ambient temperature. A line 1240 fit to these points with a robust fitting algorithm is overlaid with the points 1230. The slope of this line 1240 is equated with

$$\frac{{k}_{i}}{p C O P} ,$$

and using the average on-power of the compressor with an assumed typical COP of 1.7, we obtain kᵢ=2.83 W/° C. This is near expected leakage rates of 0.5-1.5 W/° C.

The detector and/or analyzer described herein may be implemented in hardware or by any combination of hardware, software and/or firmware. For example, in some embodiments, all or part of the analyzer may be implemented in hardware. In some embodiments, the analyzer may be implemented by a microcontroller implementing software instructions stored in a computer readable medium.

The foregoing description of various embodiments has been presented for the purposes of illustration and description and not limitation. The embodiments disclosed are not intended to be exhaustive or to limit the possible implementations to the embodiments disclosed. Many modifications and variations are possible in light of the above teaching.

1. A system comprising:
a detector configured to sample power consumption to obtain a power consumption time series having resolution sufficient to extract power cycle information for one or more individual components of a thermostat-controlled cycling appliance; and
an analyzer configured to extract the power cycle information from the sampled power consumption time series, to compare the power cycle information to stored information of known power cycle characteristics and to classify technology of the one or more components of the appliance based on comparison of the power cycle information to the stored information, the analyzer being further configured to generate an output that indicates the technology.

2. The system of claim 1, wherein the analyzer is configured to use the power cycle information to determine one or more of:
usage patterns of the appliance; and
fault or degradation conditions of the appliance.

3. The system of claim 1, wherein:
the appliance is a refrigerator system; and
the analyzer is configured to identify the components of the refrigerator system, wherein the components include one or more of a defroster, an ice-maker, a water dispenser, and a chamber light.

4. The system of claim 1 wherein:
the one or more components include a defroster; and
the analyzer is configured to identify the technology of the defroster as one of timed defroster technology and sensor controlled defroster technology based on time intervals between power cycles of the defroster.

5. The system of claim 1, wherein:
the one or more components include a compressor; and
the analyzer is configured to identify the technology of the compressor as one or more of vapor compression compressor technology, variable speed compressor technology, and fixed speed compressor technology based on detection of at least one of amplitude spikes in the power cycles of the compressor and dynamically changing amplitude of the power cycles of the compressor.

6. The system of claim 1, wherein the analyzer is further configured to classify one or more of brand, model, age, and overall efficiency of the appliance.

7. The system of claim 6, wherein the analyzer is configured to determine a readiness for replacement/recycling indicator for the appliance based on one or more of the brand, the model, the age, and the overall efficiency of the appliance.

8. The system of claim 1, wherein the analyzer is further configured to detect one or more of fault and degradation conditions of the appliance from the power cycle information.

9. The system of claim 1, wherein the analyzer is configured to detect changes in operating characteristics of the appliance based on one or a combination of long time scale information collected over more than one month and short time scale information collected over less than one hour.

10. The system of claim 9, wherein the analyzer is configured to establish a baseline of performance of the appliance and to compare the short time scale information to the baseline to detect a fault condition.

11. The system of claim 9, wherein the analyzer is configured to:
compare the long time scale power cycle information of the appliance under similar ambient conditions; and
to detect gradual degradation based on the comparison.

12. The system of claim 1, wherein the power cycle information comprises one or more power cycle parameters and the analyzer is configured to detect degradation of the appliance based on transient analysis of the one or more power cycle parameters.

13. The system of claim 1, wherein the analyzer is configured to determine usage patterns of the appliance based on statistical analysis of the power cycles of the appliance.

14. A method, comprising:
sampling power consumption at a frequency sufficient to discern power cycles for one or more individual components of a thermostat-controlled cycling appliance;
obtaining power cycle information from the sampled power consumption;
comparing the power cycle information to stored information of known power cycle characteristics;
classifying technology of the one or more components of the appliance based on comparison of the power cycle information to the stored information; and
generating an output that indicates the technology of the one or more components.

15. The method of claim 14, further comprising determining one or more of brand, model, and age of the appliance based on the technology of the one or more components.

16. The method of claim 14, further comprising determining usage patterns of the appliance.

17. The method of claim 14, further comprising providing targeted communications to consumers having one or more of a predetermined component technology, brand, model, usage pattern, overall efficiency, and fault/degradation condition of the appliance.

18. A system comprising:
a detector configured to sample power consumption to obtain a power consumption time series having resolution sufficient to extract one or more power cycle parameters of a thermostat-controlled cycling appliance; and
an analyzer configured to extract the power cycle parameters from the sampled power consumption time series, to determine a usage event transient response of the power cycle parameters to a usage event, and to detect one or more of degradation and fault conditions of the appliance based on the usage event transient response, the analyzer further configured to generate an output that indicates at least one of the detected degradation and the fault conditions.
